(19) United States
(12) Patent Application Publication
(10) Pub. No.: US 2013/0033269 A1
(43) Pub. Date: Feb. 7, 2013

(54) Fuse Tester And Puller

(71) Applicant: Qing He, North Andover, MA (US)

(72) Inventor: Qing He, North Andover, MA (US)

(21) Appl. No.: 13/395,734

(22) PCT Filed: Apr. 19, 2011
(86) PCT No.: PCT/US11/33129

§ 371 Date: Oct. 25, 2012

Related U.S. Application Data
(60) Provisional application No. 61/325,644, filed on Apr. 19, 2010.

(51) Int. Cl. G01R 31/327

(52) U.S. Cl. 324/550

(57) ABSTRACT

A fuse tester (20) that includes a plurality of contacts (22, 24) with one of the contacts (24) having pad portions (102, 104, 106) enabling connection with one spade (44, 46) of a plurality of sizes of fuses (28a, 28b, 28c) when the other spade (44, 46) is electrically connected to the other contact (22). The contact (24) has a length greater than the other contact (24) that can be a plurality of times longer. The contacts (22, 24) are anchored to a housing (26) that can be an integral part of a handle (36) of a fuse puller (32) having a pair of outwardly extending clamp arms (116, 118). A preferred puller (32) with built-in tester (20) disposes the contacts (22, 24) in an outer surface (84) of the handle (36) with the handle (36) and arms (116, 118) providing a handgrip (38) orienting the tester (20) for use when the handle (36) is grasped by a user (42) in a position enabling use of the puller (32) and tester (20). The handle (36) and arms (116, 118) are mirrored about a centerline (154) providing ambidextrous construction.

### FIELD

The present invention relates to a fuse tester and more particularly to a continuity tester usable with a hand held fuse puller that can be built into the fuse puller.

### BACKGROUND

There have been many attempts in the past to make a fuse puller or extractor, including attempts to include a built-in continuity tester or checker used to check whether a particular fuse is good or bad. The puller or extractor typically includes a clamp, such as a tweezers or forceps type clamp, at one end with outwardly extending electrically conductive test prongs at the opposite end. One known plastic fuse puller with a built-in tester is disclosed in U.S. Pat. No. 7,394,343, which has one prong that is movable relative to the other prong between a plurality of positions enabling adjustment for fuses of different sizes and capacities. Making one of the test prongs movable increases the number of parts and complexity of the tool, which in turn makes molding more complicated and costly, requires additional assembly steps, is more expensive to make, and is prone to a prong breaking or the case coming apart during use. Normal use is also not without disadvantage as the user must change their grip from one position in order to use the tool to pull or extract a fuse to another position in order to use the tool to test or check a fuse as a result of the prongs sticking out the end opposite the puller.

What is needed is a fuse puller that overcomes at least some of these disadvantages.

### SUMMARY

The present invention is directed to a fuse tester having a plurality of spaced apart electrical connectors configured to enable continuity testing of a plurality of different sizes of spade or blade type fuses having electrical fuse terminals or spades varying in width and spade-to-spade spacing as well as fuse housing length. One of the electrical connectors of the fuse tester is configured to enable contact with one spade of a plurality of different types or sizes of blade-type fuses while the other spade is in contact another one of the electrical connectors of the fuse tester. Preferably, the one of the electrical connectors of the fuse tester is a contact configured to enable contact with one spade of a plurality of pairs, i.e., at least three, of different types or sizes of blade-type fuses while the other spade is in contact with another one of the electrical connectors of the fuse tester that preferably is a contact. In one preferred embodiment, the one of the electrical contacts of the fuse tester is configured to enable electrical contact with a spade of one of a MAXI blade-type fuse, a regular sized blade-type fuse, and a mini blade-type fuse that can be a low profile mini blade-type fuse while the other spade of the fuse is in electrical contact the other spade of the MAXI, regular sized, or mini blade-type fuse.

The electrical contacts of the fuse tester are electrically connected to a power source, such as a battery or the like, and to an indicator, such as a light or lamp, e.g. LED, or the like in a series electrical circuit configuration that activates the indicator when the spades of a functional or good fuse are disposed in simultaneous contact with the electrical contacts of the fuse tester. The electrical contacts of the fuse tester are anchored to a housing made of an electrically insulating material, such as plastic, with the power source and indicator carried by the housing. In a preferred embodiment, the electrical contacts of the fuse tester are immovably fixed to the housing and exteriorly exposed permitting direct physical contact between the spaced apart blades of the fuse and a respective one of the electrical contacts of the fuse tester.

In a preferred embodiment, the fuse tester includes a first contact that is smaller than a second contact having an extent, preferably length, along which part of a fuse spade contacts during testing that is smaller than that of the second contact. The first contact has an extent, preferably length, large enough to accommodate electrical connection with one of the spades of a plurality of types or sizes of fuses the tester and the second contact is spaced from the first contact having an extent, preferably length, large enough so that the other one of the spades of a plurality of types or sizes of fuses can simultaneously make an electrical connection with the second contact.

In a preferred embodiment, the second contact of the fuse tester is elongate and has a length longer than the first contact and can be configured to have a length that is a plurality of times greater than the length of the first contact. In one preferred embodiment, the length of the second contact is at least a plurality of times greater than the length of the first contact, e.g., a plurality of pairs of times greater in length.

Each contact is a contact plate made of an electrically conductive material, such as metal, that enables an electrical connection to be established between a corresponding one of the spades spade of a blade-type fuse being tested. At least one of the contacts of the fuse tester can be slightly recessed within an outer surface of the housing to which the contact is fixed providing an upraised housing edge that serves as a fuse spade locator or seat helping to keep a spade of a blade-type fuse being tested on the fuse tester contact. In a preferred embodiment, each fuse tester contact is disposed in an aperture formed in an outer surface of the housing providing an upraised side edge defining at least part of the aperture that serves as a fuse spade locator or seat.

The fuse tester contacts are aligned and disposed in part of an outer housing surface that is a fuse testing face that can include the indicator. In a preferred embodiment, the testing face, including the fuse tester contacts, are part of a fuse puller with the fuse tester being integrally built into the fuse puller. Where the fuse tester is built into a fuse puller, part of the housing defines a handle carrying the tester with the handle configured along with fuse-engaging clamp arms to provide a handgrip that is manually grasped by a hand of a user. Another part of the housing extends outwardly from the handle defines the clamp arms used to engage and extract a blade type fuse from a socket or other type of receptacle.

The fuse testing face is disposed in part of the outer surface of the handle thereby keeping the fuse tester contacts from being covered by any part of a hand grasping the handle. The handgrip is configured to enable use of the tester and the clamp arms of the fuse puller without having to reorient the handle relative to a hand grasping the handle. In a preferred embodiment, the handle and arms are configured to provide a handgrip that is grasped by a handle of a user in a power grip or pinch grip with part of the palm of the user disposed toward or against a back surface of the handle, a thumb of the user engaging part of the handle adjacent or along one side of the handle, and one or more fingers of the user engaging part of the handle adjacent or along an opposite side of the handle. In use, the arms are pinched together between the thumb and one of the fingers, e.g., forefinger, to urge them toward a fuse engaging position.

The clamp arms extend outwardly from the sides of the handle with one arm being movable relative to the other arm toward the other arm in a direction generally parallel to the testing face and contacts enabling a fuse to be grasped therebetween when manual pressure, e.g., pinching pressure, is applied while grasping the handle. The arms extend outwardly from the handle in generally the same direction with the arms converging towards one another at an acute angle therebetween in one embodiment and being generally parallel to one another in another embodiment. Each arm has a fuse shoulder or head engaging hook at or adjacent its free end that engages or abuts against a shoulder formed by a flange of a head of a housing of a blade-type fuse during removal. When the arms engage a fuse being pulled, the fuse has a lengthwise direction oriented generally perpendicular to the testing face. One or both arms include a stop or abutment spaced from the hook that overlies and can abut the head of a plate-type fuse being removed.

A fuse puller having a built-in fuse tester constructed in accordance with the present invention has a housing with the handle and clamp arms mirrored about a longitudinally extending center line extending through a center of the handle providing substantially symmetric construction that produces a handle and puller that can be grasped by either hand. In one preferred embodiment, the handle has a teardrop or circular shape with a pair of sides converging to form a curved end and that extend outwardly forming the sides of the arms producing a handgrip of ambidextrous construction. The arms extend outwardly from the handle converging toward the center line at their free end in one embodiment, are generally parallel to one another and to the center line in another embodiment, and can include a generally outwardly bowed or arched fuse engaging segment, e.g., C-shaped, at or adjacent the free end of each arm in a still further embodiment.

Another preferred fuse tester embodiment includes a fuse tester constructed in accordance with the present invention that is integrally formed as part of a fuse puller holder that includes a pocket for releasably holding a tweezers or forceps type fuse puller or extractor. Such a fuse puller holder can be made of plastic and mountable to a vertical surface, such as a retail display or a peg board in a garage or workshop.

### DRAWING DESCRIPTION

One or more preferred exemplary embodiments of the invention are illustrated in the accompanying drawings in which like reference numerals represent like parts throughout and in which:

FIG. 1 is a top perspective view of a fuse puller with a built-in fuse tester constructed in accordance with the present invention;

FIG. 2 is a top perspective view of the fuse puller with built-in fuse tester of FIG. 1 showing use of the tester with a plurality of different fuses as well as depicting fuse puller operation;

FIG. 3 is a bottom perspective view of the fuse puller with built-in fuse tester of FIG. 1;

FIG. 4 is a front elevation view of a spade-type fuse;

FIG. 5 is a second preferred embodiment of a fuse puller with a built-in fuse tester;

FIG. 6 is a third preferred embodiment of a fuse puller with a built-in fuse tester; and

FIG. 7 front elevation view of a fuse puller holder that includes a fuse tester constructed in accordance with the present invention.

Before explaining one or more embodiments of the invention in detail, it is to be understood that the invention is not limited in its application to the details of construction and the arrangement of the components set forth in the following description or illustrated in the drawings. The invention is capable of other embodiments, which can be practiced or carried out in various ways. Also, it is to be understood that the phraseology and terminology employed herein is for the purpose of description and should not be regarded as limiting.

### DETAILED DESCRIPTION

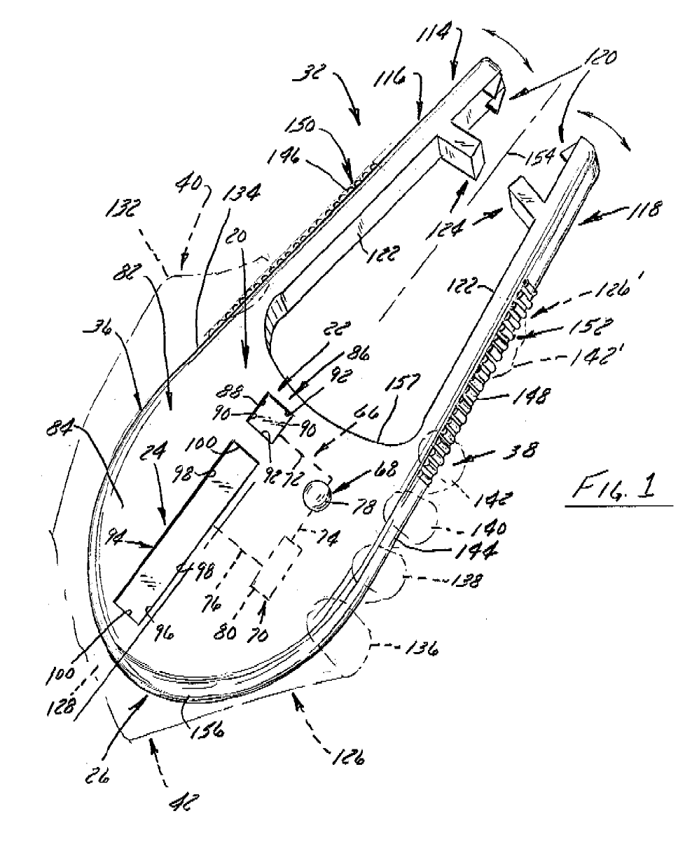

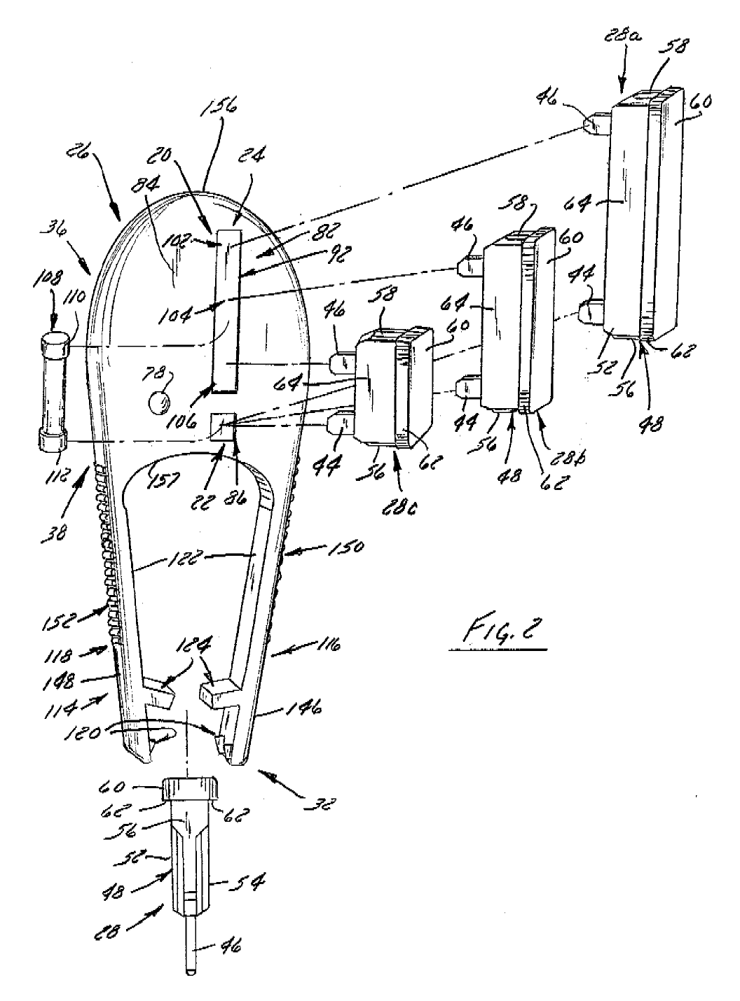

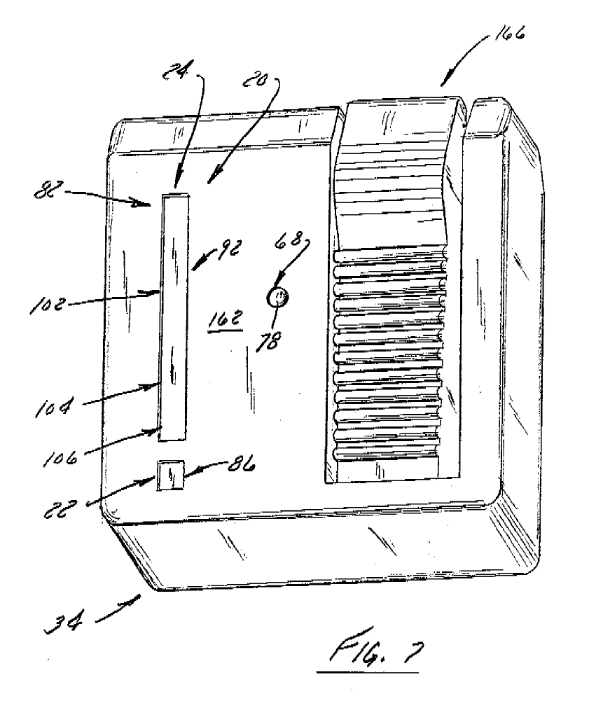

FIGS. 1-3 illustrate a preferred embodiment of a fuse tester 20 having a plurality of spaced apart electrically conductive connectors 22 and 24 anchored to a housing 26 and configured to enable testing of a plurality of types, sizes and/or ratings of spade-type fuses 28a-28c (FIG. 2) commonly used for automotive and marine applications. The tester 20 can be part of a fuse puller integrally formed of the housing 26, such as depicted in FIGS. 1-3 and 5-6, or can be part of a fuse or fuse puller holder 34, such as depicted in FIG. 7. Where the tester 20 integrally is formed with or part of a fuse puller 32, the housing 26 includes a handle 36 carrying the tester 20 that provides an ambidextrous grip 38 configured to be held by either hand 40 (shown in phantom in FIG. 1) of a user 42 in an ergonomic position that allows either fuse testing or fuse extraction without having to adjust or change the gripping position of the hand 40 grasping the handle 36.

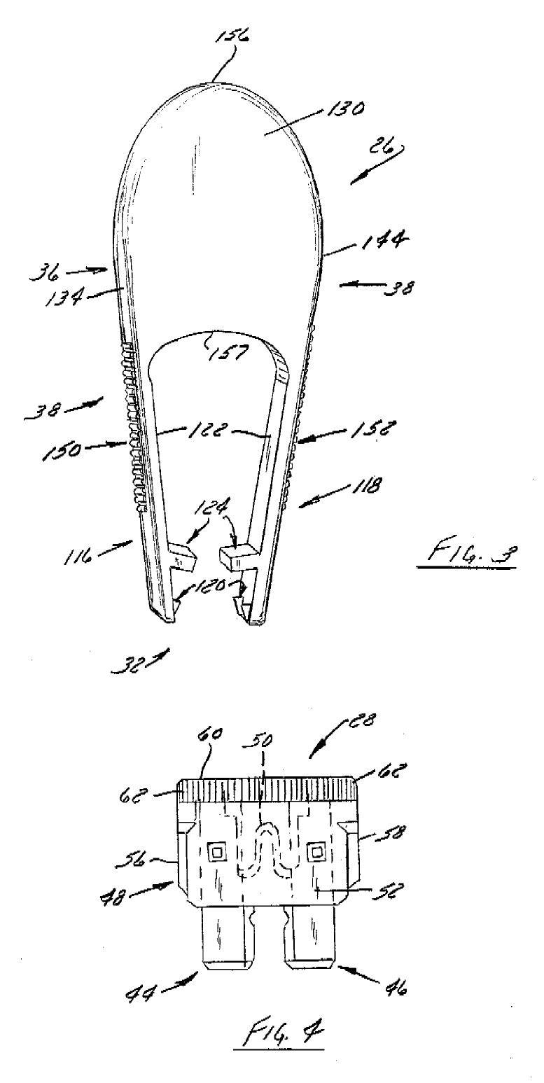

FIG. 3 illustrates a plurality of pairs, i.e., at least three, of types of spade-type fuses with one of the fuses 28a being a larger MAXI blade-type fuse, such as an APX fuse, a second one of the fuses 28b being an intermediate regular sized blade-type fuse, such as an APR, ATC or ATO fuse, and a third one of the fuses 28c being a mini blade-type fuse, such as an APM or ATM fuse, and which can be a low profile mini fuse, such as an APS fuse. With additional reference to the representative blade-type fuse 28 shown in FIG. 4, each blade-type fuse includes aligned blades or spades 44 and 46 that extend outwardly from a fuse housing 48 encompassing a sacrificial fuse element or link 50 interconnecting the spades 44 and 46. The fuse housing 48 is a generally rectangular electrically insulating box typically made of plastic having a pair of sidewalls 52 and 54, a pair of endwalls 56 and 58, a head 60 defined by an outwardly extending fuse puller engageable shoulder 62, and a skirt 64 extending downwardly from the head 60 that houses the fuse element 50.

With reference to FIG. 1, the fuse tester 20 shown in FIGS. 1-3 and 5-7 includes a continuity tester having a continuity testing circuit 66 (shown in phantom in FIG. 1) that includes an indicator 68 powered by an electrical power source 70 electrically connected in series by electrical leads 72, 74 and 76 including to respective tester connectors 22 and 24. The indicator 68 provides an indication perceptible to the user 42 when a fuse, e.g., fuse 28a, 28b, or 28c, being tested is good or functional such that electricity flows through one of the connectors 22 or 24 from one spade 44 through the sacrificial fuse element 50 to the other spade 46 through the other one of the connectors 22 or 24. In a preferred tester embodiment, the indicator 68 is configured to provide a visually perceptible indication when a fuse being tested is good. One suitable visually perceptible indicator 68 is a lamp 78, such as a light emitting diode, e.g. LED, or the like, which is anchored to the housing 26 of the tester 20. If desired, the indicator 68 can be or otherwise further include a touch sensitive, auditory perceptible or vibrating indicator, such as a transducer, e.g., buzzer or speaker, or the like. In a preferred embodiment, the power source 70 is a battery 80, such as one or more button cells, disposed within the housing 26 of the housing 20. If desired, the power source 70 can be or otherwise include another type of power source, such as a solar cell, a linear electrical generator, or another type of power source that is disposed onboard the tester 20.

The connectors are contacts 22 and 24 aligned to accept the spades of a fuse being tested defining a fuse testing face 82 that can and preferably does include the indicator 68 with the indicator 68 located adjacent the aligned contacts 22 and 24 so a user can obtain an indication whether a particular fuse being tested is functional while the fuse is being tested. Fuse testing face 82 can be a flat or generally planar portion of the outer surface 84. Outer surface 84 can be flat or generally planar as depicted in FIGS. 1-2 and 5-7.

With reference to FIGS. 1-2, the contacts 22 and 24 are plates made of an electrically conductive material, such as metal, e.g., steel, fixed to the housing 26 so as to be immovably anchored to the housing 26 so each contact plate 22 and 24 does not move relative to the outer surface 84 of the housing 26. As is shown in the drawings, each contact plate 22 and 24 is generally flat forming a contact of simple and economical construction. If desired, each contact plate 22 and 24 can be molded-in-place with the housing 26 or configured to be snapped in place, such as by being snapped to part of the housing 26, such as an interiorly disposed portion of the housing.

Contact plate 22 is a home contact plate 22 that has an extent sufficient to accommodate a spade 44 or 46 of a MAXI spade-type fuse 28a enabling electrical contact to be made with the spade when the fuse 28a is positioned relative to the tester 20 with at least a portion of one of its spades 44 or 46 in physical contact with the contact plate 22. In the home contact plate 22 shown in FIGS. 1-2 and 4-6, the extent of the home contact plate 22 is the length of the contact plate 22, which can be generally rectangular, e.g., square, as shown. In a preferred embodiment, the contact plate 22 has an extent that is a length of between about six millimeters and about eight millimeters enabling contact to be made with mini spade-type fuses 28c having a spade width of as little as about 2.7 millimeters as well as to be made with MAXI spade-type fuses 28a having a spade width as great as about eight millimeters.

Contact plate 24 is spaced from the home contact plate 22 disposing part of the electrically insulating housing therebetween. Contact plate 24 is spaced from the home contact plate 22 by a distance that enables one of the spades 44 or 46 of a mini spade-type fuse 28c to be disposed in electrical contact with one of the contact plates 22 and 24 and the other one of the spades 44 or 46 of the mini spade-type fuse 28c to be simultaneously disposed in electrical contact with the other one of the contact plates 22 or 24. In a preferred embodiment, the contact plates 22 and 24 are spaced apart by a distance of about five millimeters enabling mini spade-type fuses 28c as well as regular and MAXI spade-type fuses 28a and 28b to be tested.

Contact plate 24 is a landing contact plate 24 having an extent generally in line with the extent of the home contact plate 22 thereby enabling both spades 44 and 46 of a spade-type fuse 28a-28c to make simultaneous physical contact with a corresponding one of the contact plates 22 and 24 to test the fuse. Landing contact plate 24 has an extent that is a plurality of times the extent of the home contact 22 and which can be as great as a plurality of times the extent of the home contact 22. As is shown in FIGS. 1-2 and 5-7, the landing contact plate 24 is elongate and generally rectangular with the landing contact plate 24 being disposed generally in line with the home contact plate 22. In a preferred embodiment, the landing contact plate 24 has an extent that is a length of the contact plate 24 of at least about twelve millimeters and can be as long as about twenty four millimeters. In one preferred embodiment, the landing contact plate 24 has a length of between twelve and eighteen millimeters. In one preferred embodiment, the landing contact plate 24 has a length of about sixteen millimeters.

The home contact plate 22 can be configured to provide a spade seat or locator 86 that helps keep a spade 44 or 46 disposed on the contact plate 22 when placed against the contact plate 22, such as in preparation for testing as well as during testing. With reference to FIG. 1, the home contact plate 22 is recessed at least slightly relative to the housing outer surface 84 with the outer surface 84 having an aperture 88 formed in it that exposes the contact plate 22 enabling physical and electrical contact to be made with a spade 44 or 46 during testing. The aperture 88 is defined by two pairs of upraised generally parallel sides 90, 92 that upraised side edges define the seat or locator 86 that helps keep a spade 44 or 46 urged against the contact plate 22 in contact with the contact plate 22 by preventing the spade 44 or 46 from sliding off the contact plate 22. In a preferred embodiment, the outer surface 84 of the tester housing 26 is configured with such an aperture 88 with upraised sides 90 and 92 that provide a spade seat or locator 86.

The landing contact plate 24 can also be configured with a spade seat or locator 94 of similar or like construction where the contact plate 24 is recessed at least slightly relative to the housing outer surface 84. With continued reference to FIG. 1, the seat or locator 94 is defined by an aperture 96 provided by upraised side edges of two pairs of sides 98, 100. A pair of the aperture sides 98 that define the aperture 96 exposing the landing contact plate 24 are generally parallel with a pair of aperture sides 90 that define the aperture 88 exposing the home contact plate 22 such that the home contact plate 22 and landing contact plate 24 are generally aligned.

With reference to FIG. 2, the home contact plate 22 is smaller than the landing contact plate 24 as it has an extent or length so a spade 44 of one of a plurality of different sizes of blade-type fuses 28a, 28b and 28c can be brought into contact with the home contact plate 22 before or substantially simultaneously as the other spade 46 is brought into contact with the landing contact plate 24. The relative spacing between the home contact plate 22 and landing contact plate 24 along with the length of the landing contact plate 24 enables the tester 20 to be used with a plurality of different sized blade-type fuses 28a, 28b and 28c and preferably a plurality of pairs, i.e., at least three, different sized blade-type fuses 28a, 28b and 28c.

With continued reference to FIG. 2, to enable the tester 20 to be able to test a plurality of different sized blade-type fuses 28a, 28b and 28c, and to be able to test a plurality of pairs of fuses 28a, 28b and 28c, the landing contact plate 24 has a first blade contact pad portion 102 spaced relative to the home contact plate 22 to enable the tester 20 to check MAXI blade-type fuses 28a, a second blade contact pad portion 104 spaced relative to contact plate 22 to enable the tester 20 to check regular blade-type fuses 28b, and a third contact pad portion 106 spaced relative to contact plate 22 to enable the tester 20 to check mini blade-type fuses 28c. As is also shown in FIG. 2, the first, second and third pad portions 102, 104 and 106 are formed of a single continuous and elongate contact plate 24. Such a tester construction advantageously not only enables a plurality of different sized blade-type fuses 28a, 28b and 28c to be tested, but the configuration of the home and contact plates 22 and 24 also enable glass tube type fuses, such as the glass tube type fuse 108 shown in FIG. 2 to be tested thereby enabling a plurality of different types of fuses to be tested. As is depicted in FIG. 2, the glass tube type fuse 108 has a pair of end cap fuse contacts 110 and 112 that are respectively brought into contact with a corresponding one of the contact plates 22 and 24 in testing the fuse 108.

As previously discussed, the tester 20 can be part of a fuse puller 32, e.g. fuse remover or extractor, with the tester 20 built into the puller 32. For example, as is shown in FIGS. 1 and 2, the tester 20 is carried by a housing 26 of the puller 32 that is configured to provide a handle 36 configured to provide a handgrip 38 that can be of ambidextrous construction enabling a right-handed or left-handed user to hold the handle 36 with the tester 20 facing toward the user while still also being able to use the puller 32. To enable extraction of a blade-type fuse, e.g., blade-type fuse 28a, 28b or 28c, from a socket of a fuse box or the like, the puller 32 has a tweezers or forceps fuse head engaging clamp 114 formed of a pair of spaced apart, flexible and resilient clamp arms 116 and 118 that each have a pair of fuse shoulder engaging hooks 120 at or adjacent their free end that extend outwardly from an interior arm surface 122. One or both arms 116 and 118 can have an outwardly projecting fuse head stop 124 that overlies the head 60 of a fuse 28a, 28b or 28c during fuse removal.

The handgrip 38 is configured to permit a user 42 to grip the handle using either their right hand or their left hand 40 in a power grip configuration or pinch grip configuration enabling pressure to be manually applied to squeeze one or both arms 116 and 118 toward one another when engaging a fuse 28, such as to remove the fuse 28. For example, FIG. 1 illustrates a left hand 40 of a user 42 gripping the handle 36 in a power grip configuration 126 where part of a palm 128 of the user 42 underlies a rear surface 130 (FIG. 3) of the handle 36, a thumb 132 engages one side 134 of the handle 36, and a plurality of fingers 136, 138, 140, and 142 engage the other side 144 of the handle 36. To apply manual pressure, the thumb 132 and/or at least one of the fingers 136, 138, 140 and 142, such as the index finger 142, grip the sides 134 and 144 of the handle 36 adjacent and along a portion of an outer side 146 and/or 148 of one or both of the arms 116 and 118 to pinch and move one of the clamp arms 116 relative to the other one of the clamp arms 118 bringing their free ends toward one another causing the hooks 120 engage part of a fuse 28 sought to be removed at or adjacent its shoulder 62. The arms 116 and 118 are squeezed together until their free ends engage the fuse 28, such as depicted in FIG. 2, the handle 36 is pulled in a direction away from the fuse 28 thereby pulling the fuse 28 out of any socket or receptacle in which it was seated. As is shown in FIG. 2, during extraction, the fuse 28 is oriented with its lengthwise direction generally perpendicular to the testing face 82.

As is shown in FIG. 1, a segment of the outer side 146 and 148 of the clamp arms 116 and 118 is upraised or three dimensionally contoured providing thumb and/or finger grip engagement sections 150 and 152 that can be elongate so as to enable the thumb 132 and one or more fingers 136, 138, 140, and 142 to more positively engage a corresponding side 146 and 148 of a respective arm 116 and 118. Where the index finger 142′is extended outwardly as depicted in FIG. 1 so as to engage a portion of finger grip engagement section 152 at a position in between where the clamp arm 118 connects with the handle 36 and the free end of the clamp arm 118, the power grip configuration 126 can being modified slightly into a pinch grip configuration 126′ that can better apply squeezing or pinching pressure to clamp arm 118 during fuse pulling or extraction. This advantageously is done without having to reorient the handle 36 relative to the palm 128 of the user 42 grasping the handle 36. To help facilitate the application of manual squeezing pressure during fuse pulling or extraction, the end of the thumb 132 can also be slid farther along part of finger grip engagement section 150 of the corresponding arm 116 to more directly squeeze the arm 116 towards arm 118.

To enable ambidextrous use by either hand, the handle 36 and the clamp arms 116 and 118 are symmetric about a longitudinally extending center line 154 extending through a center of the handle 36 in between the arms 116 and 118. As is shown in FIG. 2, one of the arms 116 is disposed on one side of the center line 154 alongside the line 154 and the other one of the arms 118 is disposed on the other side of the center line 154 alongside the line 154. The sides 134 and 144 of the handle 36 converge to form an end 156 opposite the arms 116 and 118 that is curved or rounded to facilitate being held in part of a hand, e.g. palm 128 of hand 40, of a user, such as by ergonomically conforming to part of the palm located adjacent the wrist. The sides 134 and 144 of the handle 36 integrally form respective outer sides 146 and 148 of corresponding arms 116 and 118 with the arms 116 and 118 integrally formed of the housing 26 and extending outwardly from an opposite end 157 of the handle 36 converging toward one another at an acute angle relative to the center line or line of symmetry 154 and at an acute angle relative to one another.

When being held between the thumb 132 and one or more fingers 136, 138, 140 and/or 142 of the hand, e.g., hand 40, of a user 42, the symmetric construction of the handle 36 and outwardly extending arms 116 and 118 of the fuse puller 32 enable the contact plates 22 and 24 of the testing face 82 to remain facing away from the hand 40 of the user 42 during use of the fuse puller 32 thereby enabling the fuse tester 20 to be used while the handle 36 is being held in a manner where also can be used as a fuse puller or extractor. As a result, the contact plates 22 and 24 are exposed enabling use of the tester 20, including before, during and after use of the fuse puller 32.

In the preferred embodiment shown in FIGS. 1-3 and 5-6, the fuse tester 20 is built-in to the handle 36 of a housing 26 integrally formed to include a fuse puller 32 having a pair of outwardly extending arms 116 and 118 with the handle 36 and arms 116 and 118 forming a generally U-shaped puller 32 that preferably is substantially symmetric about a longitudinally extending center line 154. The testing face 82 of the tester 20 is integrally formed of part of the outer or front surface 84 of the handle 36, which can be substantially flat or generally planar in the region where the contact plates 22 and 24 are disposed. As is shown in FIGS. 1-2, the generally aligned contact plates 22 and 24 are disposed generally parallel to and adjacent center line 154 to facilitate ergonomic use of the fuse tester 20 while being held by the user. If desired, one or both contact plates 22 and 24 can be disposed along or on the center line 154. The rear outer surface 130 of the handle 36 can also be substantially planar or flat, such as depicted in FIG. 3, but can formed to be curvilinear or have three dimensional contour if desired, such as to help conform the rear surface 130 of the handle 36 to part of the hand and/or fingers of a user holding the handle 36.

The sides 134 and 144, end 156, and front and rear surfaces 84, 130 of the handle 36, along with grip portions 150 and 152 of respective arms 116 and 118 adjacent the handle 36 define a handgrip 38 of ergonomic and ambidextrous construction. Such a handgrip advantageously enables use of the fuse puller 32 while the fuse tester 20 is oriented in a manner that also permits a fuse 28 to be tested. More particularly, the configuration of the handgrip presents the contact plates 22 and 24 of the testing face 82 outwardly generally toward a user holding the handle 36 enabling spades or terminals of a fuse 28a, 28b or 28c to make contact with the contact plates 22 and 24 to test the fuse with the user not having to re-orient the handle 36 in their hand in order to use the fuse puller 32.

The housing 26, including the handle 36, and the arms 116 and 118 are preferably formed of an electrically insulating material, such as plastic or the like. Where formed of plastic, the housing 26, including the handle 36 and the arms 116 and 118 are molded so as to be of one-piece, unitary and substantially homogenous construction. In another preferred embodiment, the handle 36 and arms 116 and 118 are molded in two pieces or halves, such as front and back, with the pieces or halves snapped together or attached in another manner, e.g. glued or welded, with the contact plates 22 and 24 snapped in place before final assembly or molded in place with the front half. Automatic or manual attachment of wires 72, 74 and 76, power source 70 and indicator 68 can be done prior to assembling the halves.

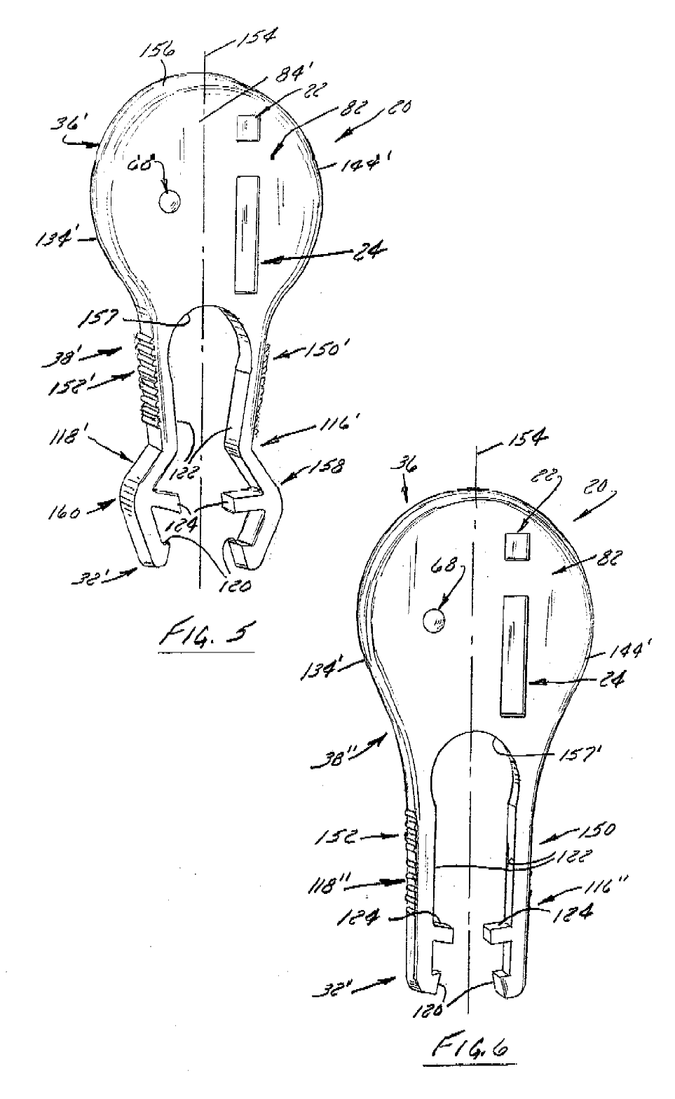

The handle 36 can have a teardrop shape like that shown in FIGS. 1-3 with each clamp arm 116 and 118 being substantially straight and converging toward center line 154 at an acute angle therewith providing a fuse puller 32 with a fuse tester 20 integrally built into the handle 36 that can be used as a puller or tester without having to reorient the handle 36 in the hand of the user. The handle 36′ can also have a generally circular front surface 84′ like that shown in FIG. 5 with the clamp arms 116′and 118′ respectively having generally straight three dimensionally contoured gripping sections 150′ and 152′ adjacent the handle 36′ that can be generally parallel or converge toward center line 154 and include generally C-shaped fuse engaging sections 158 and 160 adjacent the free end of the respective arm 116′ and 118′. In another preferred embodiment, the clamp arms 116″ and 118″ can be substantially straight and extend outwardly generally parallel to one another as well as to center line 154 about which the arms 116″ and 118″ and handle 36′ are mirrored.

FIG. 7 illustrates a fuse puller holder 34 having an outer surface 162 that includes a testing face 82 that includes a fuse tester 20 with a pair of contact plates 22 and 24 that are part of a continuity checking circuit like the circuit schematically depicted in phantom in FIG. 1 that activates an indicator 68, such as a light 78, if the fuse being checked is functional or good. The holder 34 has a pocket 164 configured to removably hold a tweezers or forceps type fuse puller 166 and can include a compartment (not shown) in which a plurality of fuses can be stored. Such a fuse puller holder 34 can be formed of plastic, such as by injection molding, with the contact plates 22 and 24 fixed in place to the holder 34. If desired, the holder 34 can be constructed to be easily hung on a peg, such as a peg of a retail display or a peg attached to pegboard in a garage or work area.

Various alternatives are contemplated as being within the scope of the following claims particularly pointing out and distinctly claiming the subject matter regarded as the invention. It is also to be understood that, although the foregoing description and drawings describe and illustrate in detail one or more preferred embodiments of the present invention, to those skilled in the art to which the present invention relates, the present disclosure will suggest many modifications and constructions, as well as widely differing embodiments and applications without thereby departing from the spirit and scope of the invention.

1. A fuse tester comprising:
a housing having an outer surface,
a first fuse-spade contact anchored to the housing configured to make electrical contact with one spade of a plurality of different sized spade-type fuses; and
a second fuse-spade contact anchored to the housing that is spaced from the first fuse-spade contact and configured to make electrical contact with the other spade of the plurality of different sized spade-type fuses.

2. The fuse tester of claim 1 wherein the second contact has an extent extending in a direction generally in line with the first contact greater than the extent of the first contact.

3. The fuse tester of claim 2 wherein the second contact has a first contact pad portion spaced from the first contact configured to make electrical contact with an ATM size spade-type fuse, a second contact pad portion spaced from the first contact so as to make electrical contact with an ATC size spade-type fuse, and a third contact pad portion spaced from the first contact so as to make electrical contact with a MAXI size spade-type fuse.

4. The fuse tester of claim 3 wherein the first and second contacts are generally rectangular and wherein the second contact has a length that is a plurality of times the length of the first contact.

5. The fuse tester of claim 4 wherein the first and second contacts each comprise a flat metal plate with the second contact being elongate.

6. The fuse tester of claim 1 further comprising a spade seat or locator that locates one of the spades of a spade-type fuse being tested on one of the first and second contacts.

7. The fuse tester of claim 6 wherein one of the first and second contacts are recessed below the outer surface of the housing providing an upraised edge around a portion of the first and second contacts defining a spade locator for each one of the first and second contacts.

8. The fuse tester of claim 1 further comprising a fuse puller integrally formed of the housing.

9. The fuse tester of claim 8 wherein the housing comprises a handle carrying the first and second contacts configured to orient the fuse puller and fuse tester so both the fuse puller and fuse tester are usable without changing an orientation of the handle in a hand of a user manually gripping the handle.

10. The fuse tester of claim 9 wherein the fuse puller comprises a fuse engaging clamp having a plurality of arms with one of the arms movable toward the other one of the arms toward a fuse engaging position when pinched between a thumb and finger of a user.

11. The fuse tester of claim 10 wherein the handle and the arms comprise a power or pinch handgrip.

12. The fuse tester of claim 11 wherein the first and second contacts and at least a portion of the outer surface of the housing define a fuse testing face and wherein one of the arms is movable relative to the other one of the arms in a direction generally parallel to the fuse testing face.

13. The fuse tester of claim 12 wherein the handle and arms are mirrored about a longitudinally extending centerline thereof defining an ambidextrous handgrip.

14. The fuse tester of claim 13 wherein the handle has a pair of side walls extending along the fuse testing face that form an outer side of a corresponding one of the clamp arms.

15. The fuse tester of claim 14 wherein the clamp arms engage a fuse during extraction orienting the fuse so a lengthwise direction of the fuse is generally perpendicular relative to the testing face.

16. The fuse tester of claim 1 wherein the housing comprises a handle from which a pair of flexible fuse puller clamp arms outwardly extend that form a fuse puller, the handle having a palm-facing surface on one side, a fuse testing surface opposite the palm-facing surface comprising the first and second contacts, and a pair of outer sides that extend along a portion of a corresponding one of the clamp arms forming a handgrip grasped by a hand of a user where the tester and clamp arms are usable without reorienting the handle relative to the hand during fuse testing and fuse pulling.

17. The fuse tester of claim 16 wherein the sides of the handle converge to form one handle end and wherein the clamp arms extend outwardly from an opposite handle end.

18. The fuse tester of claim 17 wherein each side of the handle defines a side of a corresponding one of the clamp arms.

19. The fuse tester of claim 18 wherein the clamp arms are movable relative to one another toward one another in a direction generally parallel to the fuse testing surface.

20. The fuse tester of claim 19 wherein handle and clamp arms are symmetric about a longitudinally extending centerline that extends through a center of the handle.

21. The fuse tester of claim 1 wherein the housing is comprised of plastic.

22. The fuse tester of claim 1 wherein the first and second contacts comprise a continuity testing circuit having a power source and an indicator.

23. The fuse tester of claim 1 wherein the first and second contacts each comprise a metal plate.

24. A fuse tester and puller comprising:
a housing having an outer surface comprising a handle having a pair of spaced apart fuse-engaging clamp arms extending outwardly from the handle;
a first fuse-spade electrical connector carried by the outer surface of the housing and disposed on the handle, the first connector configured to make electrical contact with one spade of a plurality of different sized spade-type fuses;
a second fuse-spade electrical connector carried by the outer surface of the housing and disposed on the handle, the second connector spaced from the first connector and configured to make electrical contact with the other spade of the plurality of different sized spade-type fuses.

25. The fuse tester and puller of claim 24 wherein the first and second connectors are fixed to the housing and wherein the second connector is longer than the first connector.

26. The fuse tester and puller of claim 25 wherein the first and second connectors each comprise a metal plate.

27. The fuse tester and puller of claim 26 wherein the first and second connectors are aligned and generally rectangular forming a fuse testing face.

28. The fuse tester and puller of claim 24 wherein the handle and a portion of each clamp arm comprise a pinch grip handgrip.

29. The fuse tester and puller of claim 24 wherein the first and second connectors form a fuse testing face that is generally parallel to a direction of movement of one of the clamp arms relative to the other one of the clamp arms during fuse pulling.

30. The fuse tester and puller of claim 24 wherein the handle and clamp arms are symmetric about a center line extending through a center of the handle between the clamp arms with one of the clamp arms disposed on one side of the center line and the other one of the clamp arms disposed on the other side of the center line.

31. A method of operating a fuse tester having a fuse puller comprising:
(a) providing a housing comprising a handle having a pair of spaced apart fuse-engaging clamp arms extending outwardly from the handle and defining a handgrip and a plurality of spaced apart electrical connectors carried by the handle defining a fuse testing face;
(b) grasping the handle; and
(c) pinching one of the clamp arms toward the other one of the clamp arms engaging a fuse therebetween.

32. The method of claim 31 wherein during the pinching step (c) the one of the arms moves toward the other one of the arms in a direction generally parallel to the fuse testing face.

33. The method of claim 31 wherein during the grasping step (b) a hand of a user grasps the handle in a power grip or pinch grip.

34. The method of claim 31 the step further comprising testing a fuse without reorienting the handle.

35. The method of claim 31 wherein the electrical connectors comprise an electrical contact with one of the electrical contacts having an extent greater than the other one of the electrical contacts and the steps further comprising (1) placing one blade of a first blade-type fuse having a first size and distance between blades against one of the contacts and placing the other blade of the first blade-type fuse against the other one of the contacts testing the first blade-type fuse and (2) placing one blade of a second blade-type fuse having a second size and distance between blades that is larger than the first blade-type fuse against the one contact and the other blade of the second blade-type fuse against the other contact testing the second blade-type fuse.
